(19) United States
(12) Patent Application Publication
(10) Pub. No.: US 2015/0235681 A1
(43) Pub. Date: Aug. 20, 2015

(54) PSEUDO-DIFFERENTIAL READ SCHEME FOR DUAL PORT RAM

(71) Applicant: Nvidia Corporation, Santa Clara, CA (US)

(72) Inventors: Gang Chen, Shanghai (CN); Jing Guo, Shanghai (CN); Yiqi Wang, Shanghai (CN); Hwong-Kwo Lin, Santa Clara, CA (US)

(73) Assignee: Nvidia Corporation, Santa Clara, CA (US)

(21) Appl. No.: 14/279,796

(22) Filed: May 16, 2014

(30) Foreign Application Priority Data
Feb. 14, 2014 (CN) 201410052592.1

(51) Int. Cl. G11C 7/12

(52) U.S. Cl. CPC G11C 7/12

(57) ABSTRACT

A memory read system includes a memory column having a plurality of dual port memory cells that are controlled by separate read word lines and a read bit line structure organized into upper and lower read bit line portions. Additionally, the memory read system also includes a pseudo-differential memory read unit coupled to the read bit line structure, wherein the upper and lower read bit line portions respectively control corresponding upper and lower local bit lines to provide a global bit line for the memory column. A method of reading a memory is also included.

### CROSS-REFERENCE TO RELATED APPLICATION

This application claims priority to Chinese Application No. 201410052592.1, filed on Feb. 14, 2014, which is incorporated herein by reference.

### TECHNICAL FIELD

This application is directed, in general, to a data storage memory and, more specifically, to a memory read system and a method of reading a memory.

### BACKGROUND

In dual port memory cells, read and write operations can be executed concurrently and therefore employ independent read and write bit lines that are controlled by corresponding separate read and write word lines. When the stored memory cell data represents a “TRUE” condition, a precharged voltage on the read bit line needs to be discharged in order to reflect this TRUE condition. A corresponding discharge time of the read bit line is affected by bit line capacitance and the discharge voltage level that is required to indicate the memory cell's TRUE storage condition. For longer discharge times, the reading speed of the memory cell can be relatively slow for large capacity memory arrays. This is due to read current capability, which is often limited in magnitude due to small memory cell areas. Additionally, larger discharge voltages typically require larger dynamic power expenditures. Therefore, improvements in these areas would prove beneficial to the art.

### SUMMARY

Embodiments of the present disclosure provide a memory read system and a method of reading a memory.

In one embodiment, the memory read system includes a memory column having a plurality of dual port memory cells that are controlled by separate read word lines and a read bit line structure organized into upper and lower read bit line portions. Additionally, the memory read system also includes a pseudo-differential memory read unit coupled to the read bit line structure, wherein the upper and lower read bit line portions respectively control corresponding upper and lower local bit lines to provide a global bit line for the memory column.

In another aspect, the method of reading a memory includes providing a memory column of dual port memory cells controlled by separate read word lines and organizing a read bit line structure for the memory column into upper and lower memory cell read bit line portions. The method also includes controlling corresponding upper and lower local read bit lines from the upper and lower memory cell read bit line portions during a read operation and controlling a global read bit line for the memory column from the upper and lower local read bit lines to provide a memory cell storage state during the read operation.

The foregoing has outlined preferred and alternative features of the present disclosure so that those skilled in the art may better understand the detailed description of the disclosure that follows. Additional features of the disclosure will be described hereinafter that form the subject of the claims of the disclosure. Those skilled in the art will appreciate that they can readily use the disclosed conception and specific embodiment as a basis for designing or modifying other structures for carrying out the same purposes of the present disclosure.

### BRIEF DESCRIPTION

Reference is now made to the following descriptions taken in conjunction with the accompanying drawings, in which:

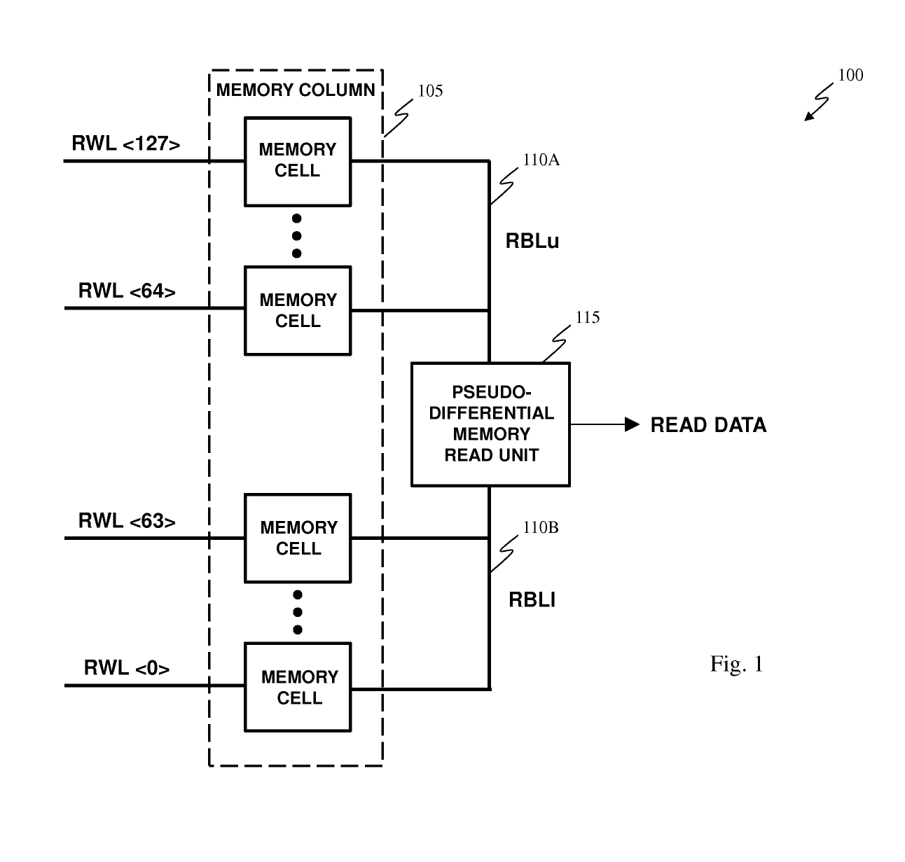

FIG. 1 illustrates a block diagram of an embodiment of a memory read system constructed according to the principles of the present disclosure;

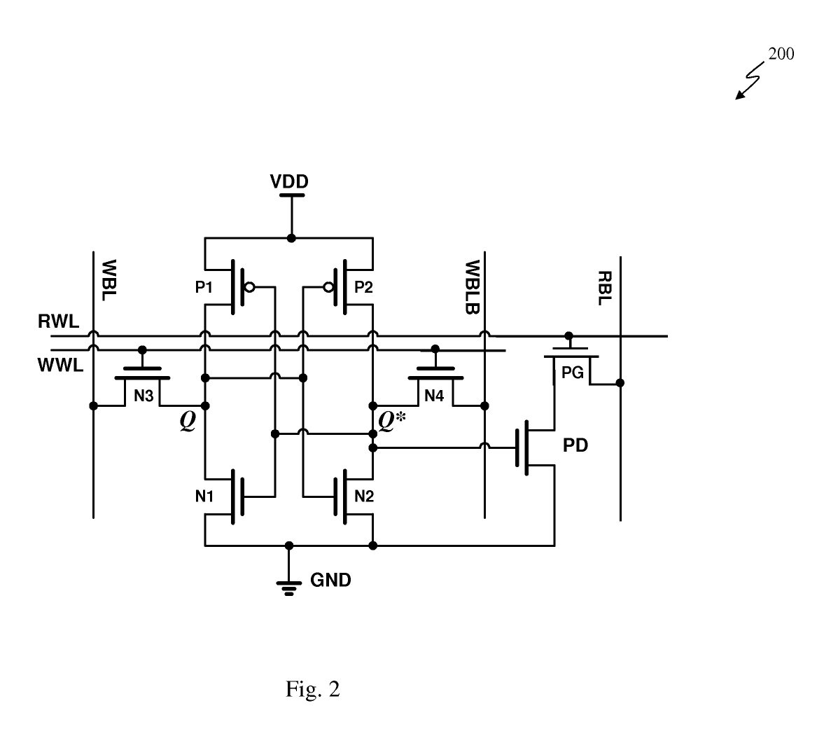

FIG. 2 illustrates a schematic diagram of a dual port SRAM cell as may be employed in the memory column of FIG. 1;

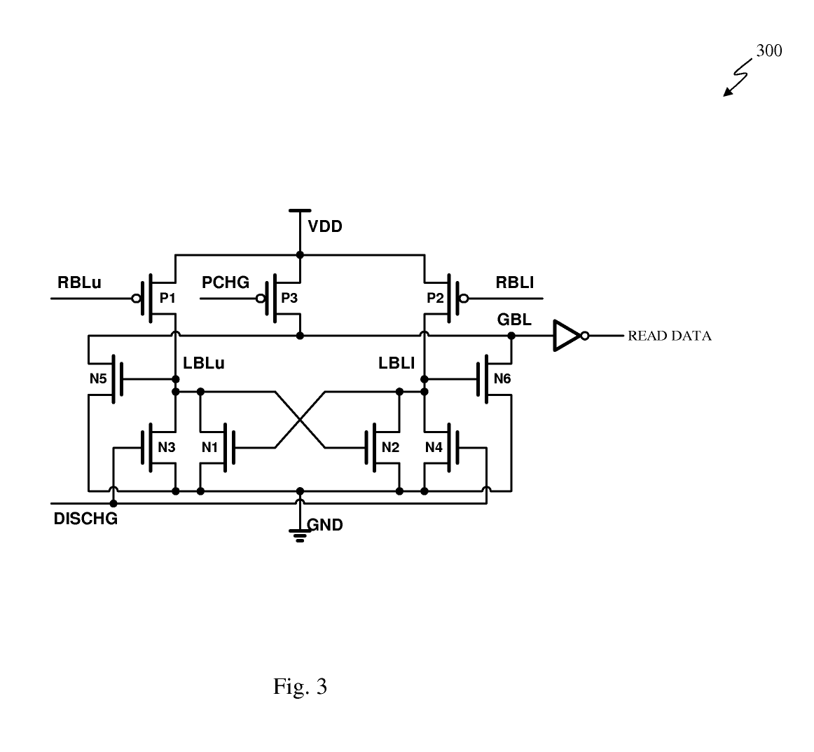

FIG. 3 illustrates a schematic diagram of an embodiment of a pseudo-differential memory read unit as may be employed as the pseudo-differential memory read unit of FIG. 1;

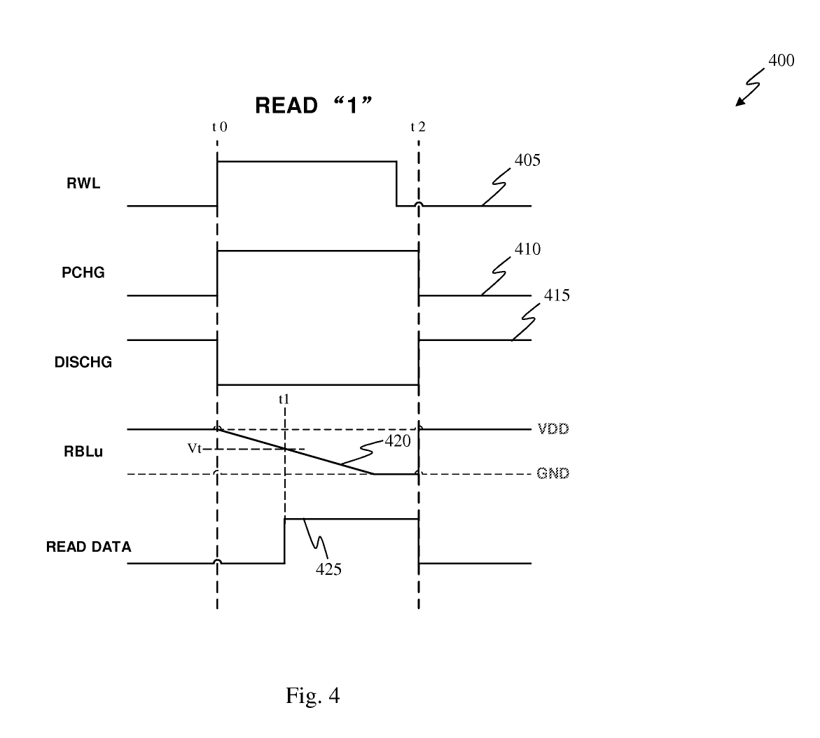

FIG. 4 illustrates a waveform timing diagram corresponding to a read operation for a memory read system constructed according to the principles of the present disclosure; and

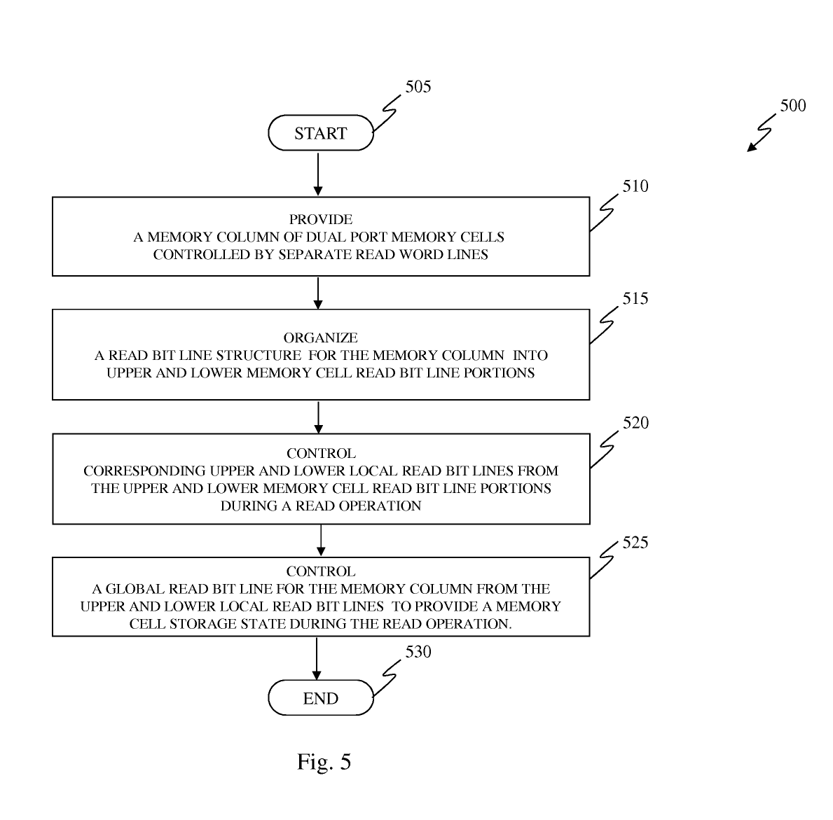

FIG. 5 illustrates a flow diagram of a method of reading a memory carried out according to the principles of the present disclosure.

### DETAILED DESCRIPTION

Embodiments of the present disclosure provide a pseudo-differential read capability for dual port memory cells (e.g., dual port static random access memory (SRAM) cells), which improves read speed and decreases dynamic power requirements by reducing a required read voltage swing. These attributes are especially beneficial as memory capacity increases.

FIG. 1 illustrates a block diagram of an embodiment of a memory read system, generally designated 100, constructed according to the principles of the present disclosure. Here, the memory read system 100 is representative of a bit column employing separate read and write bit lines in a memory array containing 128 words. The memory read system 100 includes a memory column 105, upper and lower read bit line portions 110A, 110B and a pseudo-differential memory read unit 115.

In the illustrated embodiment, the memory column 105 includes a plurality of dual port memory cells that are controlled by separate read word lines (RWL<0> through RWL<127>), where only one of the separate read word lines is activated during a read operation. The upper and lower read bit line portions 110A, 110B constitute a read bit line structure for the memory column 105 that provides a memory cell storage condition for a selected read word line during a read operation. The read bit line structure provides for lower stray or intrinsic overall bit line capacitance thereby decreasing an overall read time for the memory column 105.

The pseudo-differential memory read unit 115 is coupled to the read bit line structure, as shown. The upper and lower read bit line portions 110A, 110B respectively control corresponding upper and lower local bit lines within the pseudo-differential memory read unit 115 to provide a global read bit line for the memory column 105.

FIG. 2 illustrates a schematic diagram of a dual port SRAM cell, generally designated 200, as may be employed in the memory column 105 of FIG. 1. The dual port SRAM (SRAMDP) cell 200 may be written into and read from concurrently and includes first and second CMOS inverters N1:P1 and N2:P2 that are cross coupled to provide a memory cell having complementary storage nodes Q and Q*, as shown. The cross-coupled CMOS inverters N1:P1 and N2:P2 are powered by a supply voltage VDD.

The SRAMDP cell 200 also includes corresponding first and second write pass gate transistors N3 and N4 that are respectively connected between a write bit line WBL and the storage node Q and a complementary write bit line WBLB and the complementary storage node Q*. The first and second write pass gate transistors N3 and N4 are controlled by a write word line WWL.

The SRAMDP cell 200 additionally includes a read pass gate transistor PG that is connected between a read bit line RBL and an inverting transistor PD. The read pass gate transistor PG is controlled by a read word line RWL.

The SRAMDP cell 200 is representative of one of the memory cells in the memory column 105 of FIG. 1. Here, the read bit line RBL shown in FIG. 2 is representative of one of the upper (RBLu) and lower (RBL1) read bit line portions 110A, 110B that constitute a read bit line structure for the memory column 105. The read bit line RBL is precharged to a positive voltage (e.g., the supply voltage VDD) prior to a read operation and then reflects a TRUE or FALSE state of the SRAMDP cell 200 during the read operation.

FIG. 3 illustrates a schematic diagram of an embodiment of a pseudo-differential memory read unit, generally designated 300, as may be employed as the pseudo-differential memory read unit 115 of FIG. 1. The pseudo-differential memory read unit 300 includes upper and lower local bit lines LBLu, LBL1 that are coupled to a global bit line GBL to provide a READ DATA output, which indicates a TRUE or FALSE state of a memory cell in a memory column during a read operation.

Also included are control transistors P1 and P2, which are respectively used as read input devices for the upper and lower local bit lines LBLu, LBL1 and where their controlling gates are connected to upper (RBLu) and lower (RBL1) read bit line portions of a bit line structure (such as those previously discussed). Additionally included is a control transistor P3 that is employed to precharge the global bit line GBL to a supply voltage VDD, prior to a read operation.

Further included are transistors N1 and N2 that are employed as a reinforcing cross-coupling circuit between the upper and lower local bit lines LBLu, LBL1 to improve a noise margin of the global bit line GBL. Still further included are control transistors N3 and N4 that are employed to discharge the upper and lower local bit lines LBLu, LBL1 to ground potential outside of a read operation.

Yet further included are transistors N5 and N6 that perform as a wire NOR2 logic circuit and are employed to couple the upper and lower local bit lines LBLu, LBL1 to the global bit line GBL during a read operation. Correspondingly, the transistors N5 and N6 are employed to provide isolation of the upper and lower local bit lines LBLu, LBL1 from the global read bit line GBL outside of a read operation.

If the stored data of a corresponding memory cell represents a “FALSE” state (i.e., a logical “zero” condition), a voltage level of the upper (RBLu) and lower (RBL1) read bit line portions is maintained at a precharge voltage VDD and the READ DATA output reflects this FALSE state or zero condition. Otherwise, the READ DATA output will be changed to reflect a “TRUE” state or logical “one” condition of the corresponding memory cell.

FIG. 4 illustrates a waveform timing diagram, generally designated 400, corresponding to a read operation for a memory read system constructed according to the principles of the present disclosure. The waveform timing diagram 400 reflects a read operation of a pseudo-differential memory read unit (such as shown in FIG. 3) and includes a read word line (RWL) waveform 405, a precharge (PCHG) waveform 410, a discharge (DISCHG) waveform 415, an upper read bit line portion (RBLu) waveform 420 and a READ DATA output waveform 425. The waveform timing diagram 400 represents reading a TRUE state (i.e., a “one” condition) for a memory cell served by an upper read bit line (RBLu) portion of a bit line structure.

Before a read operation begins (i.e., prior to time t0), the RWL waveform 405 indicates that a read word line RWL is in a LOW voltage state. Correspondingly, upper and lower read bit line portions RBLu, RBL1 of a bit line structure have been precharged to a precharge voltage VDD. The PCHG waveform 410 indicates that a precharge control signal PCHG is in a LOW voltage state, and the DISCHG waveform 415 indicates that a discharge control signal DISCHG is in a HIGH voltage state. Upper and lower local bit lines LBLu, LBL1 are discharged to a ground potential (control transistors N3, N4 are conducting and transistors N5, N6 are not conducting), and the global bit line GBL is precharged to a precharge voltage VDD. These conditions maintain the READ DATA output in a FALSE state, when not performing a read operation.

When the RWL waveform transitions to a HIGH voltage state at time t0, the read operation begins. The PCHG waveform 410 also transitions to a HIGH voltage state thereby deactivating the control transistor P3 and leaving the global bit line GBL charged to the precharge voltage VDD. The DISCHG waveform 415 transitions to a LOW voltage state thereby deactivating the control transistors N3, N4 and isolating the upper and lower local bit lines LBLu, LBL1. The precharge voltage VDD of the RBLu waveform 420 begins to discharge, which reflects a TRUE state for the memory cell being addressed for reading by the read word line RWL.

As this discharge continues, a threshold voltage Vt of the control transistor P1 is reached (at time t1) thereby causing it to conduct, which activates the transistor N5 and thereby pulls the global bit line GBL to ground potential. This global bit line state provides a TRUE state for the READ DATA waveform 425 indicating the TRUE state of the addressed memory cell. The read operation is concluded at time t2, and all of the waveforms return to their previous states before the read operation began.

Simulation results for embodiments of the present disclosure employing a 128 row random access memory indicates an 11 percent improvement in a worst case read speed over a traditional read scheme (411 picoseconds versus 460 picoseconds). Here, the worst case read speed is defined as the delay time from the rising edge of the read word line to the rising edge of the READ DATA output signal. Correspondingly, there is a 12 percent decrease in required RBLu discharge voltage (513 millivolts versus 584 millivolts), which translates to about a 12 percent dynamic power improvement.

FIG. 5 illustrates a flow diagram of a method of reading a memory, generally designated 500, carried out according to the principles of the present disclosure. The method 500 starts in a step 505, and a memory column of dual port memory cells controlled by separate read word lines is provided, in a step 510. Then, a read bit line structure for the memory column is organized into upper and lower memory cell read bit line portions, in a step 515. Corresponding upper and lower local read bit lines are controlled from the upper and lower memory cell read bit line portions during a read operation, in a step 520. A global read bit line for the memory column is controlled from the upper and lower local read bit lines to provide a memory cell storage state during the read operation, in a step 525.

In one embodiment, the upper and lower memory cell read bit line portions are initially precharged to a memory supply voltage level before a read operation. In another embodiment, the upper and lower local read bit lines are initially discharged before a read operation. Correspondingly, the discharge of the upper and lower local read bit lines isolates them from the global read bit line. In yet another embodiment, a voltage discharge from the initially precharged voltage level of one of the upper and lower memory cell read bit line portions controls a voltage discharge of the global bit line. In still another embodiment, a reinforcing cross-coupling between the upper and lower local read bit lines improves a global read noise margin.

In a further embodiment, the global read bit line is initially precharged to a memory supply voltage level before a read operation. In a yet further embodiment, the global read bit line is separately controlled by each of the upper and lower local read bit lines, wherein the separately controlled global read bit line employs a two transistor wire NOR circuit. In a still further embodiment, the global read bit line is coupled to an inverter circuit to provide a read data output. The method 500 ends in a step 530.

While the method disclosed herein has been described and shown with reference to particular steps performed in a particular order, it will be understood that these steps may be combined, subdivided, or reordered to form an equivalent method without departing from the teachings of the present disclosure. Accordingly, unless specifically indicated herein, the order or the grouping of the steps is not a limitation of the present disclosure.

In summary, advantages provided by embodiments of the present disclosure employing a pseudo-differential memory read approach include:
1) A read speed improvement and a dynamic power reduction through reducing of a required voltage swing of the upper (RBLu) and lower (RBL1) read bit line portions;
2) A reduction or elimination of DC current requirements from traditional control logic connected to the upper (RBLu) and lower (RBL1) read bit line portions; and
3) A reduction in total required semiconductor chip area thereby allowing larger capacity memory arrays to be accommodated for a same read speed.

Those skilled in the art to which this application relates will appreciate that other and further additions, deletions, substitutions and modifications may be made to the described embodiments.

What is claimed is:

1. A memory read system, comprising:
a memory column having a plurality of dual port memory cells that are controlled by separate read word lines and a read bit line structure organized into upper and lower read bit line portions; and
a pseudo-differential memory read unit coupled to the read bit line structure, wherein the upper and lower read bit line portions respectively control corresponding upper and lower local bit lines to provide a global bit line for the memory column.

2. The system as recited in claim 1 wherein a reinforcing cross-coupling circuit is included between the upper and lower local bit lines to improve a noise margin of the global read bit line.

3. The system as recited in claim 1 wherein a discharge circuit is included to provide a discharge of the upper and lower local bit lines outside of a read operation.

4. The system as recited in claim 3 wherein the discharge of the upper and lower local bit lines isolates them from the global read bit line.

5. The system as recited in claim 1 wherein the global read bit line is initially precharged to a memory supply voltage level before a read operation.

6. The system as recited in claim 1 wherein the upper and lower read bit line portions are initially precharged to a memory supply voltage level before a read operation.

7. The system as recited in claim 6 wherein a voltage discharge from the initially precharged voltage level of one of the upper and lower read bit line portions controls a voltage discharge of the global bit line.

8. The system as recited in claim 1 wherein the global bit line is separately coupled to each of the upper and lower local bit lines.

9. The system as recited in claim 8 wherein the separately coupled global bit line employs a two transistor wire NOR circuit.

10. The system as recited in claim 1 wherein the global read bit line is coupled to an inverter circuit for a read data output.

11. A method of reading a memory, comprising:
providing a memory column of dual port memory cells controlled by separate read word lines;
organizing a read bit line structure for the memory column into upper and lower memory cell read bit line portions;
controlling corresponding upper and lower local read bit lines from the upper and lower memory cell read bit line portions during a read operation; and
controlling a global read bit line for the memory column from the upper and lower local read bit lines during the read operation.

12. The method as recited in claim 11 wherein a reinforcing cross-coupling between the upper and lower local read bit lines improves a global read noise margin.

13. The method as recited in claim 11 wherein the upper and lower local read bit lines are discharged outside of a read operation.

14. The method as recited in claim 13 wherein the discharge of the upper and lower local read bit lines isolates them from the global read bit line.

15. The method as recited in claim 11 wherein the global read bit line is initially precharged to a memory supply voltage level before a read operation.

16. The method as recited in claim 11 wherein the upper and lower memory cell read bit line portions are initially precharged to a memory supply voltage level before a read operation.

17. The method as recited in claim 16 wherein a voltage discharge from the initially precharged voltage level of one of the upper and lower memory cell read bit line portions controls a voltage discharge of the global bit line.

18. The method as recited in claim 11 wherein the global read bit line is separately controlled by each of the upper and lower local read bit lines.

19. The method as recited in claim 18 wherein the separately controlled global read bit line employs a two transistor wire NOR circuit.

20. The method as recited in claim 11 wherein the global read bit line is coupled to an inverter circuit to provide a read data output.
